(19) United States
(12) Patent Application Publication
(10) Pub. No.: US 2017/0223860 A1
(43) Pub. Date: Aug. 3, 2017

(54) FRONT CABLE MANAGEMENT ASSEMBLY

(71) Applicant: HEWLETT PACKARD ENTERPRISE DEVELOPMENT LP, Houston, TX (US)

(72) Inventors: Morgan A Jones, Houston, TX (US); Minh H NGUYEN, Katy, TX (US); Peter SZCZESNIAK, Houston, TX (US)

(21) Appl. No.: 15/328,484

(22) PCT Filed: Jul. 31, 2014
(86) PCT No.: PCT/US2014/049065

§ 371 Date: Jan. 23, 2017

(51) Int. Cl. H05K 7/14; G06F 1/18

(52) U.S. Cl. CPC H05K 7/1491; G06F 1/181

(57) ABSTRACT

A front cable management assembly for a server rack includes a first assembly bracket and a second assembly bracket and a cable rail movably coupled to the first and the second assembly brackets. The first and the second assembly brackets are to be mounted to a front of a server rack. The cable rail is positioned in between the first and the second assembly brackets and is to move to a first position and a second position while movably coupled to the first and the second assembly brackets.

### BACKGROUND

A server rack can include a metal framework designed to support a plurality of servers (e.g., devices that respond to requests across a network to provide, or help provide, a service). The server rack can contain multiple mounting slots, called bays, each designed to hold a server and/or other network equipment secured in place with screws. A single server rack can contain a plurality of servers stacked one above the other, consolidating network resources and minimizing the required flow space. Each of the servers can include a plurality of cables for power, communication, and/or other purposes.

### BRIEF DESCRIPTION OF THE DRAWINGS

FIGS. 1A-1B illustrate diagrams of an example of a front cable management assembly according to the present disclosure;

FIG. 2 illustrates a diagram of an example of a front cable management system according to the present disclosure; and

FIGS. 3A-3C illustrate diagrams of examples of front cable management systems according to the present disclosure.

### DETAILED DESCRIPTION

Server racks with installed servers can include a vast number of cables. For instance, each server installed can have cables for power, communication, and/or other purposes. A single rack can contain a plurality of servers stacked one above one another, resulting in a plurality of loose cables in the front of the server rack. The loose cables can get tangled and obstruct access to bays of the server rack.

Managing the cables in the front of the server rack can be beneficial to reduce service time to equipment in the server rack, such as installing a server. A cable management assembly can be used to manage the cables by organizing the cables in the front of the server rack. Some cable management assembly solutions may be mounted to the server rack and the cables can be attached to the assembly. However, in order to service an installed server or install/uninstall a server in the server rack, the entire chassis and/or server rack may be powered down. Powering down an entire chassis and/or server rack can cause network disruption, for example.

Further, some assembly solutions support a particular server and/or other equipment height. Thus, a different assembly can be used for each server or other equipment that has a different height. For instance, a server rack with a first server of 5 rack units and a second server of 6.5 rack units installed can have two different assemblies to mount to support both servers.

In contrast, examples of the present disclosure include a front cable management assembly for a server rack that can be used to organize cables of equipment installed in the server rack in a way that allows a server and/or other equipment to be serviced without powering down the entire chassis and/or rack. For example, a front cable management assembly in accordance with the present disclosure can include a cable rail movably coupled to two assembly brackets and is to move to a first position and a second position while movably coupled to the two assembly brackets. The two assembly brackets can be mounted to a server rack. A cable rail can include a support extending from the two assembly brackets and can support cables for equipment of the server rack. The second position can, for instance, be an open position of the front cable management assembly that allows access to a particular server for servicing and/or allows access to a bay of the server rack. The particular server can be serviced, for instance, while the remaining portions of the server rack have power. In addition, the front cable management assembly can support equipment of varying heights.

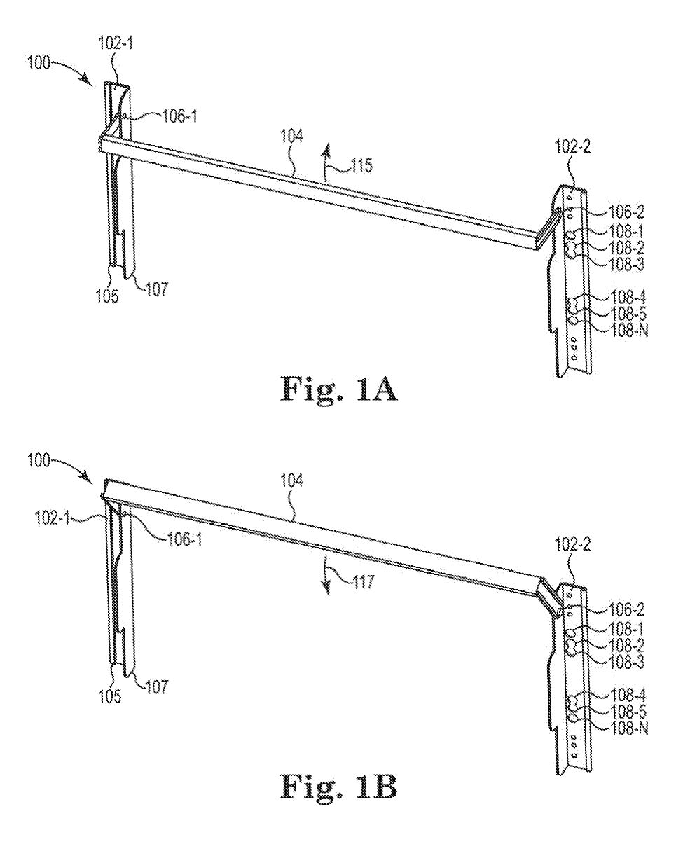

FIGS. 1A-1B illustrate diagrams of an example of a front cable management assembly 100 according to the present disclosure. The front cable management assembly 100 illustrated in FIG. 1A can be a front cable management assembly with a cable rail 104 in a first position. The front cable management assembly 100 illustrated in FIG. 1B can be the front cable management assembly with the cable rail 104 in a second position.

As illustrated by FIGS. 1A-1B, a front cable management assembly 100 can include a first assembly bracket 102-1 and a second assembly bracket 102-2. An assembly bracket, as used herein, is a support for the cable rail. An example bracket can include a metal bracket; however, examples in accordance with the present disclosure are not so limited and the assembly brackets can be made of a variety of material (e.g., plastic, wood, rubber, etc.). The assembly brackets 102-1, 102-2 can be mounted to a front of a server rack, as discussed further herein.

The first and the second assembly brackets 102-1, 102-2 can be L-shaped brackets, as illustrated by FIG. 1A-1B. A side 107 of a first assembly bracket 102-1 (and a second assembly bracket 102-2) can be a portion of the L-shaped bracket that protrudes out from a server rack when the assembly bracket 102-1 is mounted to the server rack. A front 105 of the assembly bracket 102-1 can be a portion of the L-shaped bracket that is mounted to a front of the server rack, as further discussed herein.

“Mounting the assembly brackets to the server rack” and “mounting the front cable management assembly to the server rack” are used herein interchangeably and bath are intended to be mounting the assembly brackets to the front of the server rack.

A server rack, as used herein, is a framework (e.g., a metal framework) designed to support a plurality of servers (e.g., computers used as a server). The server rack can contain multiple mounting slots, called bays, each designed to hold equipment secured in place with fasteners. A single server rack can contain a plurality of servers stacked one above the other, consolidating network resources and flow space. Example equipment of the server rack can include servers, switches, and/or fans, among other electronic devices. A server, as used herein, can include a device (e.g., a computing device) that responds to requests across a network to provide and/or help provide a service.

The server rack can be a rectangular shaped framework. A front of a server rack, as used herein, is a portion of the server rack (e.g., the metal framework) that a person can access to service equipment in the server rack. The assembly brackets 102-1, 102-2 can be mounted to one of the sides of the front of the server rack, as discussed further herein.

A cable rail 104 can be movably coupled to the first and the second assembly brackets 102-1, 102-2. As illustrated by FIGS. 1A-1B, the cable rail 104 is positioned horizontally in between and coupled to the first and the second assembly brackets 102-1, 102-2. The first and the second assembly brackets 102-1, 102-2 are positioned parallel to one another with the cable rail 104 horizontally positioned in between. A cable rail 104, as used herein, is a support (e.g., a bracket) extending from and/or in between the first and second assembly brackets 102-1, 102-2.

In some examples, the cable rail 104 can be coupled to the first and second assembly brackets 102-1, 102-2 via a plurality of rail fasteners 106-1, 106-2. For example, the cable rail 104 can be coupled to a first assembly bracket 102-1 via a first rail fastener 106-1 and coupled to a second assembly bracket 102.2 via a second rail fastener 106-2 so as to pivot about the first rail fastener 106-1 and the second rail fastener 106-2 while coupled to the first assembly bracket 102-1 and the second assembly bracket 102-2.

A fastener, as used herein, is a hardware device that mechanically couples two objects together (e.g., couples a cable rail to an assembly bracket). Example fasteners can include bolts, pins, nuts, and/or screws, among other hardware devices.

As illustrated by FIG. 1A-1B, the cable rail 104 can be a U-shaped rail. The U-shaped rail can include two side connecting components and a front rail component. Each side connecting component can be connected to one of assembly brackets 102-1, 102-2 via a respective rail fastener 106-1, 106-2 and can pivot about the respective rail fastener. The side connecting components can be portions of the U-shaped rail that protrude out from server rack when the cable rail 104 is coupled to the assembly brackets 102-1, 102-2 and the front cable management assembly 100 is mounted to the server rack (e.g., protrude in the same direction as the sides of the L-shaped assembly brackets, as previously discussed). A front rail component of the cable rail 104 can be a portion of the U-shaped rail that is positioned in between the first and the second assembly brackets 102-1, 102-2 when the cable rail 104 is coupled to the first and the second assembly brackets 102-1, 102-2 and/or extends across the front of the server rack when the front cable management assembly 100 is mounted to the server rack. The front rail component can be coupled to the protruding end of each of the two side connecting components. A protruding end of a side connecting component of the cable rail 104 is an end that extends farthest from the assembly brackets 102-1, 102-2 (e.g., an opposite end from the end that is connected to an assembly bracket).

Because the U-shaped cable rail 104 includes the front rail component connected to the protruding ends of the two side connecting components, the cable rail 104 can freely move positions (e.g., the first and second positions) while coupled to the first and the second assembly brackets 102-1, 102-2 and/or when the front cable management assembly 100 is mounted to the server rack. For instance, the front rail component protruding out from the server rack can prevent the cable rail 104 from interacting with the server rack and allow for movement of the cable rail 104 (e.g., the front rail component of the cable rail 104 does not interact with and/or touch the front of the server rack).

The cable rail 104 can generally be held in place in between the first and the second assembly brackets 102-1. 102-2 via friction by the first and the second rail fasteners 106-1, 106-2, but able to be moved by hand (e.g., by a user) without loosening the first or second rail fasteners 106-1, 106-2. A user can grip the cable rail 104 and apply force in a general upward or downward direction to cause the cable rail 104 to move along an arch (e.g., as illustrated by arrows 115, 117 in FIGS. 1A-1B) from the first position to the second position, and vice versa. The movement of the cable rail 104 along the arch can be in a generally upward or downward direction and generally perpendicular to the first and the second assembly brackets 102-1, 102-2.

The cable rail 104 can rotate freely along the arch until a first stop or a second stop is reached. The first stop and the second stop can a component of each of the first and the second assembly brackets 102-1, 102-2. A stop, as used herein, is a component of a respective assembly bracket that prevents the cable rail 104 from pivoting about the rail fasteners 106-1, 106-2 past a first position or a second position. For instance, the first stop can prevent the cable rail 104 from pivoting past (e.g., lower than) the first position illustrated in FIG. 1A and the second stop can prevent the cable rail 104 from pivoting past (e.g., higher than) the second position illustrated in FIG. 1B. The stops can be located on the side of the assembly bracket (e.g., the side of the L-shaped assembly brackets that protrude out from the server rack). Examples stops can include a fastener coupled to an assembly bracket and/or portions of the side of the assembly brackets that protrude out from the side of the assembly bracket in a direction that is parallel to the front of the assembly bracket (e.g., the front of the L-shaped assembly bracket that is and/or is designed to be mounted to a front of the server rack), among other stops.

The cable rail 104 can support cables for equipment of the server rack. For example, the cables can be managed by attaching the cables to the cable rail 104. For example, the cables can be attached using ties, such as zip-ties.

The cables for an installed server can remain coupled to the cable rail 104 during movement of the cable rail 104. As an example, the cable rail 104 can support cables for a server installed in between the first and the second assembly brackets 102-1, 102-2 when the front cable management assembly 100 is mounted to a front of a server rack. The cables can remain coupled to the cable rail 104 during movement of the cable rail 104 between the first position and the second position. The cables for the server can be organized using the front cable management assembly 100 during servicing of a different server and/or other equipment in the server rack (e.g., as discussed further herein).

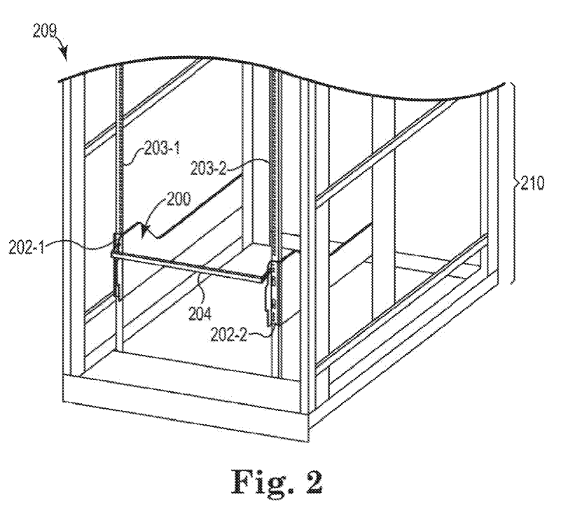

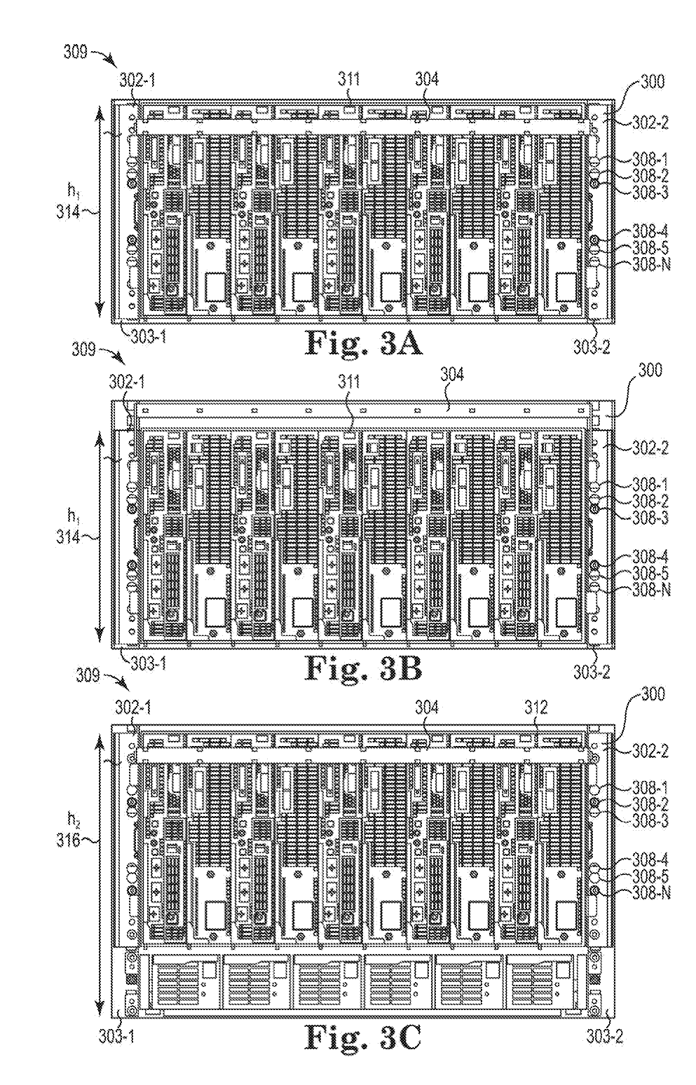

As illustrated by FIGS. 1A and 1B, the cable rail 104 can be positioned in between the first and the second assembly brackets 102-1, 102-2. Further, when the first and the second assembly brackets 102-1, 102-2 are mounted to a front of the server rack, the cable rail 104 can be positioned across the front of the server rack (e.g., as illustrated by FIG. 2 and FIGS. 3A-3C).

The cable rail 104 can be moved to the first position, as illustrated in FIG. 1A, and the second position, as illustrated in FIG. 1B, while movably coupled to the two assembly brackets 102-1, 102-2, as previously discussed. For instance, the cable rail 104 can be coupled to the first assembly bracket 102-1 via the first rail fastener 106-1 and coupled to the second assembly bracket 102-2 via the second rail fastener 106-2 so as to move to the second position from the first position along an arc (e.g., as illustrated by arrows 115 in FIG. 1A) as the cable rail 104 pivots about the first rail fastener 106-1 and the second rail fastener 106-2 while the cable rail 104 is coupled to the first and the second assembly brackets 102-1, 102-2 in the first position and in the second position.

The first position, as illustrated by FIG. 1A, can be a closed position and the second position, as illustrated by FIG. 1B, can be an open position. A first position is a position of the cable rail 104 coupled to the first and the second assembly brackets 102-1, 102-2, where the cable rail 104 is rotated about the first and the second rail fasteners 106-1, 106-2 (movement of the cable rail along an arc in a general downward direction, as illustrated by arrow 117 in FIG. 1B) until a first stop (not illustrated by FIG. 1A) is reached. For example, the arrow 117 in FIG. 1B illustrates a generally downward direction that the cable rail 104 moves along the arc to move from the second positioned illustrated in FIG. 1B to the first position illustrated in FIG. 1A.

When the cable rail 104 is in the first position, a bay of the server rack is not accessible. The bay is not accessible when the cable rail 104 is in the first position and the front cable management assembly 100 is mounted to a front of a server rack as the cable rail 104 is positioned across the front the server rack at a height (e.g., a height of the front vertical rails of the server rack, as discussed further herein) that blocks at least a portion of the bay. By blocking at least a portion of the bay, the cable rail 104 in the first position may prevent and/or make it more difficult for a user to service equipment in the particular bay as compared to an unblocked bay.

A second position is a position of the cable rail 104 coupled to the first and the second assembly brackets 102-1, 102-2, where the cable rail 104 is rotated about the first and the second rail fasteners 106-1, 106-2 (movement of the cable rail 104 along the arc in a general upward direction, as illustrated by arrow 115 in FIG. 1A) until a second stop (not illustrated by FIG. 1B) is reached. For example, the arrow 115 in FIG. 1A illustrates a generally upward direction that the cable rail 104 moves along the arc to move from the first position illustrated in FIG. 1A to the second position illustrated in FIG. 1B. The first stop can be at a lower height on the front of the server rack than the second stop.

When the cable rail 104 is in the second position, the bay of the server rack is accessible. The bay is accessible when the cable rail 104 is in the second position as the cable rail 104 is positioned across the front of the server rack at a height of the front of the server rack that does not block the bay. By not blocking the bay, the cable rail 104 in the second position can allow and/or make it is easier for a user to service equipment in the particular bay as compared to a blocked and/or partially blocked bay.

That is, a closed position of the cable rail 104 is a position in which a server and/or other equipment cannot be serviced. An open position of the cable rail 104 is a position in which a server and/or other equipment can be serviced. As previously discussed, a bay is a mounting slot of the server rack designed to hold a server and/or other equipment secured in place with fasteners.

Servicing equipment (e,g., a server), as used herein, can include installing equipment, uninstalling equipment, and/or performing an operation on installed equipment (e.g., maintenance). For example, using the front cable management assembly 100, particular servers can be serviced without disrupting power to the entire server rack and/or chassis. Thereby, a particular server can be serviced while the remaining portions of the server rack have power, as discussed further herein.

As an example, when the front cable management assembly 100 is mounted to a server rack, a server is installable in between the first and the second assembly brackets 102-1, 102-2 in the server rack while remaining portions of the server rack have power and the cable rail 104 is coupled to the first and the second assembly brackets 102-1, 102-2 is in the second position illustrated by FIG. 1B. The cable rail 104 can be coupled to a side of each of the first and the second assembly brackets 102-1, 102-2 using a plurality of rail fasteners 106-1, 106-2 and the first and the second assembly brackets 102-1, 102-2 can be coupled to the front of the server rack using a plurality of bracket fasteners (not specifically illustrated in FIGS. 1A-1B).

The coupling of the cable rail 104 to the side of each of the first and the second assembly brackets 102-1, 102-2 can allow power to the server rack to remain connected while the cable rail 104 is in the second position and a server and/or other equipment installed in the server rack in between the first and the second assembly brackets 102-1, 102-2 is accessible as the other equipment in the respective bays of the remaining server rack can each have a cable rail to manage cables of each respective piece of equipment. Thereby, a single front cable management assembly 100 can include a plurality of cables rails and/or a plurality of front cable management assemblies each with a cable rail (e.g., identical in dimensions to the front cable management assembly 100 illustrated in FIG. 1) can be mounted to a server rack, and each cable rail can be designed to manage cables for a different bay of the server rack. A particular server can be accessed by moving the cable rail 104 managing cables for the particular server to the second position and the remaining plurality of cables rails of the front cable management assembly can remain in a first position and/or can have cables coupled to (e.g., attached) the remaining cables rails. Because the cables for the remaining equipment can remain coupled to cable rails, the power to the remaining equipment of the server rack can stay connected.

The cable rail 104 in the second position illustrated by FIG. 1B can, in some instances, block and/or partially block a different bay of the server rack. For example, a first server can be installed in a first bay of a server rack and a second server can be installed in a second bay of the server rack located above the first bay. A cable rail 104 managing cables for the first server that is in a second position can block and/or partially block the second bay. Thereby, the free movement of the cable rail 104 between the first and second positions can allow for different bays of the server rack to be accessed without removal of the front cable management assembly 100.

In addition, when the cable rail 104 is in the second position, cables coupled to the cable rail 104 can be at an angle that may degrade the cables. For instance, the cables may stop working over time due to the angle of the cables when coupled to a piece of equipment (e.g., plugged-in) and the cable rail 104, and the cable rail 104 is in the second position. The movement to the first and second position can allow access to a particular bay and reduce degradation of cables.

The installed server is uninstallable (e.g., removable) in between the first and the second assembly brackets 102-1, 102-2 in the server rack while remaining portions of the server rack have power and the cable rail 104 coupled to the first and the second assembly brackets 102-1, 102-2 is in the second position. Thereby, a server can be installed and/or subsequently uninstalled without removing the front cable management assembly 100 or portions thereof from the server rack as the respective cable rail can be moved to a second position to allow access to the bay that the server is installed in and/or intended to be installed.

In a number of examples, the assembly brackets 102-1, 102-2 can be mounted to the front of the server rack using a plurality of bracket fasteners to couple each of the first and the second assembly brackets 102-1, 102-2 to the front of the server rack. Coupling of the assembly brackets 102-1, 102-2 to the front of the server rack can allow power to the server rack to remain on while the cable rail 104 is coupled to the first and the second assembly brackets 102-1, 102-2 in both the first position and the second position as the front cable management assembly 100 can remain mounted to the server rack, and thus cables for installed equipment can remain coupled to a cable rail of the front cable management assembly 100 when a particular bay is accessed by a user (e.g., when equipment is serviced).

The first and the second assembly brackets 102-1, 102-2 can be mounted to a mounting location on the front of the server rack. For instance, using a mounting opening on each of the first and the second assembly brackets 102-1, 102-2 located on the front (e.g., the front 105 of the first assembly brackets 102-1) of the assembly brackets 102-1, 102-1, the assembly brackets can be coupled to the front of the server rack.

In some examples, the first and second assembly brackets 102-1, 102-2 can support a plurality of mounting locations on a server rack. For example, the first and the second assembly brackets 102-1, 102-2 can include a plurality of mounting openings (e.g., the second assembly bracket 102-2 includes the plurality of mounting openings 108-1, 108-2, 108-3, 108-4, 108-5, . . . , 108-N), by which the first and second assembly brackets 102-1, 102-2 can be coupled to the front of the server rack (e.g., by passing a respective bracket fastener through a number of the openings 108-1. 108-2, 108-3, 108-4. 108-5, . . . , 108-N and securing it to the server rack).

A mounting location, as used herein, is a mounting position of the front cable management assembly 100 on a server rack that supports server and/or other equipment of a particular incremental height. Example mounting locations can include a 1 rack unit (RU) mounting location supporting equipment with heights that are an increment of whole number RU (e.g., whole number RU heights) and a 0.5 RU mounting location supporting equipment with heights that are an increment of a half number RU (e.g., half number RU heights), as further discussed herein.

For example, the first and the second assembly brackets 102-1, 102-2 can be mounted to a mounting location on the front of the server rack using a mounting opening of each of the first and second assembly brackets 102-1, 102-2 among a plurality of mounting openings 108-1, 108-2, 108-3, 108-4, 108-5, . . . , 108-N located vertically along a front of each of the first and the second assembly brackets 102-1, 102-2. The cable rail 104 can extend across the front of the server rack and in between the first and the second assembly brackets 102-1, 102-2.

FIG. 2 illustrates a diagram of an example of a front cable management system 209 according to the present disclosure. The front cable management system 209 can include a front cable management assembly 200 and a server rack 210. The front cable management assembly 200 can be analogous to the front cable management assembly 100 illustrated and described with respect to FIG. 1.

Similarly to FIG. 1, the front cable management assembly 200 can include a first assembly bracket 202-1 and a second assembly bracket 202-2 and a cable rail 204. The assembly brackets 202-1, 202-2 can be mounted to a front of the server rack 210.

A first assembly bracket 202-1 can be mounted to a first side 203-1 of a front of the server rack 210 and a second assembly bracket 202-2 can be mounted to a second side 203-2 of the front of the server rack 210. The sides 203-1, 203-2 of the front of the server rack 210, as used herein, are the front vertical rails of the server rack 210. The sides 203-1, 203-2 of the server rack 210, as illustrated by FIG. 2, can have a plurality of mounting openings therein. As illustrated, the plurality of mounting openings on the sides 203-1, 203-2 of the front of the server rack 210 can be located vertically along the front of the server rack 210.

As previously discussed, in some examples, the assembly brackets 202-1, 202-2 can support a plurality of mounting locations on the server rack 210 by including a plurality of mounting openings. The assembly brackets 202-1, 202-2 can be mounted to the server rack 210 by a bracket fastener coupling the mounting opening of the respective assembly bracket to a mounting opening of the server rack 210.

The plurality of mounting locations can include incremental heights of 1 RU and 0.5 RU when the first and the second assembly brackets 202-1, 202-3 are mounted on the front of the server rack 210 and the cable rail 204 is horizontally positioned across the front of the server rack 210 and in between the first and the second assembly brackets 202-1, 202-3. That is, the front cable management assembly 200 can support servers and/or other equipment with incremental heights of whole number RU and half number RU (e.g., heights that end in a whole number RU and a half number RU), as discussed further herein.

As previously discussed, the cable rail 204 can move from a first position to a second position while movably coupled to the first and the second assembly brackets 202-1, 202-2. For instance, the positions can include the first position and the second position, as illustrated by FIGS. 1A and 1B. As an example, a server can be at least one of installable and uninstallable in between the first and the second assembly brackets 202-1, 202-2 when the cable rail 204 is in the second position and coupled to the first and the second assembly brackets 202-1, 202-2.

In a number of examples, the front cable management assembly 200 can include a plurality of cable rails. Each of the plurality of cable rails can be coupled to the side of each of the first and the second assembly brackets 202-1, 202-2 and can extend across the front of the server rack 210 when the front cable management assembly 200 is mounted to the server rack 210. The cable rails can be in between the first and the second assembly brackets 202-1, 202-2, for example.

In such examples, a front cable management assembly 200 can manage cables for the plurality of servers and/or other equipment. For instance, each of the plurality of cable rails can be positioned to support cables for a server and/or other equipment installed in between the first and the second assembly brackets 202-1, 202-2 and can move from a respective first position to a respective second position. Any one of the plurality of servers and/or other equipment is serviceable when the cable rail positioned to support cables for the one server and/or other equipment is coupled to the first and the second assembly brackets 202-1, 202-2, and the cable rail is in the second position. When the one server is being serviced, the remaining plurality of servers and/or other equipment can have power. Thereby, the front cable management assembly 200 can be used to manage cables for a plurality of servers and/or other equipment and can allow for one of the plurality of servers and/or other equipment to be serviced while the remaining have power and/or cables that are managed.

FIG. 3A-3C illustrate diagrams of examples of front cable management systems 309 according to the present disclosure.

As previously discussed herein, a front cable management system 309, can include a front cable management assembly 300 mounted to a server rack (e.g., the sides 303-1, 303-2 of the front of the server rack, as previously discussed in connection with FIG. 2). The front cable management assembly 300 can include a first assembly bracket 302-1 and a second assembly bracket 302-2, and a cable rail 304 movably coupled to the first and the second assembly brackets 302-1, 302-2. The cable rail 304 can extend across the front of the server rack and in between the first and the second assembly brackets 302-1, 302-2 and/or can move to a first position and a second position while movably coupled to the first and the second assembly brackets 302-1, 302-2.

Front cable management assembles, such as those illustrated by FIGS. 3A-3C, can be used to support servers and/or other equipment of varying heights. For instance, a front cable management assembly 300 can be used to support a server with an incremental height that includes a whole number RU and an incremental height that includes a half number RU. To support the varying heights, the assembly brackets 302-1, 302-2 can include a plurality of mounting openings 308-1, 308-2, 308-3, 308-4, 308-5, 308-N (hereafter generally referred to as “mounting openings 308”).

As illustrated by FIGS. 3A-3C, the mounting openings 308 can be located on a front of each of the first assembly bracket 302-1 and the second assembly bracket 302-2 and can support a plurality of mounting locations on the front of the server rack. The mounting locations, as previously discussed, can include a mounting position of the front cable management assembly 300 on the server rack that supports equipment of a particular incremental height. The server rack can have a plurality of mounting openings on the sides of the front of the server rack that can be used to couple the assembly brackets 302-1, 302-2 to the server rack (e.g., mounting openings on each side 303-1, 303-2 of the server rack).

For example, the first and the second assembly brackets 302-1, 302-2 can be mounted to the front of the server rack at a mounting location among the plurality of mounting locations using a mounting opening of each of the first and the second assembly brackets 302-1, 302-2 among the plurality of mounting openings (e.g., as illustrated by the mounting openings 308 on the front of the second assembly bracket 302-2). The mounting openings 308 can support a server and/or other equipment installed in between the first and second assembly brackets 302-1, 302-2 mounted to the front of the server rack when the cable rail 304 is coupled to the first and the second assembly brackets 302-1, 302-2 that includes incremental heights that include a whole number RU and/or a half number RU.

For example, FIGS. 3A and 3B illustrate a server 311 installed between the first and the second assembly brackets 302-1, 302-2 that has a height 314 of 5 RU. In contrast, FIG. 3C illustrates a server 312 installed between the first and the second assembly brackets 302-1, 302-1 that has a height 316 of 6.5 RU. Examples in accordance with the present disclosure are not limited to servers with heights of 5 RU and 6.5 RU and can include a variety of heights. For example, the mounting openings 308 can be at varying RU heights such that the front cable management assembly 300 can support a plurality of servers and/or other equipment that include a variety of heights.

The front cable management assemblies 300 illustrated by FIGS. 3A-3B and 3C can include the same assembly mounted at different mounting locations of a server rack (e.g. FIGS. 3A and 3B can include the assembly mounted at a first mounting location and FIG. 3C can include the assembly mounted at a second mounting location), in some examples. Alternatively and/or in addition, the front cable management assembly 300 illustrated by FIGS. 3A, 3B and 3C can include the different assemblies of the same dimension (e.g., identical assemblies of the same height/width and with the various features described herein) mounted at different mounting locations of the same server rack. That is, a single server rack can have a plurality of assemblies mounted thereto.

FIGS. 3A-3B illustrate a server 311 installed in between the first and the second assembly brackets 302-1, 302-2 that includes a whole number RU height. A whole number RU height is a height that is an increment of 1.0 RU and ends in a whole number (e.g., 4 RU, 5 RU, 6 RU, etc.) For instance, the height 314 of the server 311 can be 5 RU.

To support the server 311, the first and the second assembly brackets 302-1, 302-2 can be mounted to a 1 RU mounting location on the server rack using a plurality of particular mounting openings (e.g., mounting openings 308-3 and 308-4 of the second assembly bracket 302-2) of the assembly brackets 302-1, 302-2 and a plurality of particular mounting openings of the server rack.

FIG. 3A, for instance, illustrates the cable rail 304 of the front cable management assembly 300 in a first position (e.g., closed position) and FIG. 3B illustrates the cable rail 304 of the front cable management assembly 300 in the second position (e.g., open position). The cable rail 304 is movably coupled to a side of each of the first and the second assembly brackets 302-1, 302-2 via a plurality of rail fasteners (not illustrated by FIGS. 3A-3B). The cable rail 304 can pivot about the plurality of rail fasteners to move positions (e.g., the first position illustrated by FIG. 3A and the second position illustrated by FIG. 3B) while coupled to the side of each of the first and the second assembly brackets 302-1, 302-2.

FIG. 3C illustrates a server 312 installed in between the first and the second assembly brackets 302-1, 302-2 that includes a half number RU height. A half number RU height is a rational number that is formed by a ratio of integers and ends in a value of 0.5 RU (e.g., 5 RU, 2.5 RU, 3.5 RU, etc.) That is, the half number RU height can be an increment of 1.0 RU starting at 0.5 RU and ends in a half number RU. The height 316 of the server 312 can, for instance, be 6.5 RU.

To support the server 312, the first and the second assembly brackets 302-1, 302-2 can be mounted to a 0.5 RU mounting location on the server rack using a plurality of particular mounting openings (e.g., mounting openings 308-2 and 308-N of the second assembly bracket 302-2) of the assembly brackets 302-1, 302-2 and a plurality of particular mounting openings of the server rack (e.g., mounting openings on each side 303-1, 303-2 of the server rack).

Although the present examples of FIGS. 3A-3C illustrate a cable rail, examples in accordance with the present disclosure are not so limited. For example, a front cable management assembly 300 in accordance with the present disclosure can include more than one cable rail.

In some examples, a single front cable management assembly can support multiple servers with varying heights. For instance, the first and the second assembly brackets 302-1, 302-2 can be mounted to the front of the server rack at a mounting location among the plurality of mounting locations using a mounting opening of each of the first and the second assembly brackets 302-1, 302-2 among the plurality of mounting openings. The mounting opening can support a first server installable between the first and the second assembly brackets 302-1, 302-2 mounted to the front of the server rack, when a first cable rail is coupled to the first and the second assembly brackets 302-1, 302-2, with an incremental height that includes a whole number RU and a second server installable between the first and the second assembly brackets 302-1, 302-2 mounted to the front of the server rack, when a second cable rail is coupled to the first and the second assembly brackets, with an incremental height that includes a half number RU.

Further, in various examples, a front cable management system 309 can include a plurality of front cable management assemblies. That is, a plurality of front cable management assemblies can be mounted to a server rack. For instance, the front cable management assembly 300 of FIG. 3A can be a first assembly mounted to a server rack, the front cable management assembly 300 of FIG. 3B can be a second assembly mounted to the server rack, and the front cable management assembly of FIG. 3C can be a third assembly mounted to the server rack. The first, second, and/or third assemblies can be mounted to the server rack at different mounting locations to support equipment in the server rack of varying heights.

As an example, a front cable management system 309 can include a first front cable management assembly and a second front cable management assembly mounted to the front of the server rack. A first and a second assembly brackets of the first front cable management assembly can be mounted to the front of the server rack at a first mounting location among the plurality of mounting locations using a mounting opening of each of the first and the second assembly brackets of the first front cable management assembly among the plurality of mounting openings to support a first server installable in between the first and the second assembly brackets with an incremental height that includes a whole number rack unit. A first and a second assembly brackets of the second front cable management assembly are mounted to the front of the server rack at a second mounting location among the plurality of mounting locations using a mounting opening of each of the first and the second assembly brackets second front cable management assembly among the plurality of mounting openings to support a second server installable in between the first and the second assembly brackets with an incremental height that includes a half number rack unit.

In the foregoing detailed description of the present disclosure, reference is made to the accompanying drawings that form a part hereof, and in which is shown by way of illustration how examples of the disclosure may be practiced. These examples are described in sufficient detail to enable those of ordinary skill in the art to practice the examples of this disclosure, and it is to be understood that other examples may be utilized and that process, electrical, and/or structural changes may be made without departing from the scope of the present disclosure.

The figures herein follow a numbering convention in which the first digit corresponds to the drawing figure number and the remaining digits identify an element or component in the drawing. Elements shown in the various figures herein can be added, exchanged, and/or eliminated so as to provide a number of additional examples of the present disclosure. In addition, the proportion and the relative scale of the elements provided in the figures are intended to illustrate the examples of the present disclosure, and should not be taken in a limiting sense. Further, as used herein, “a number of” an element and/or feature can refer to one or more of such elements and/or features.

what is claimed:

1. A front cable management assembly for a server rack, comprising:
a first assembly bracket and a second assembly bracket, wherein the first and the second assembly brackets are to be mounted to a front of a server rack; and
a cable rail movably coupled to the first and the second assembly brackets, wherein the cable rail is:
positioned in between the first and the second assembly brackets; and
is to move to a first position and a second position while movably coupled to the first and the second assembly brackets.

2. The front cable management assembly of claim 1, wherein the cable rail is coupled to the first assembly bracket via a first rail fastener and coupled to the second assembly bracket via a second rail fastener so as to pivot about the first rail fastener and the second rail fastener while coupled to the first assembly bracket and the second assembly bracket.

3. The front cable management assembly of claim 1, wherein:
the cable rail is coupled to the first assembly bracket via a first rail fastener and coupled to the second assembly bracket via a second rail fastener; and
wherein the cable rail is to move to the second position from the first position along an arc as the cable rail is to pivot about the first rail fastener and the second rail fastener while the cable rail is coupled to the first and the second assembly brackets in the first position and in the second position.

4. The front cable management assembly of claim 3, wherein:
the first and the second assembly brackets are mounted to the front of the server rack using a plurality of bracket fasteners to couple each of the first and the second assembly brackets to the front of the server rack; and
wherein the coupling of the first and the second assembly brackets to the front of the server rack allows power to the server rack to remain on while the cable rail is coupled to the first and the second assembly brackets in both the first position and the second position.

5. The front cable management assembly of claim 1, wherein:
the cable rail is coupled to a side of each of the first and the second assembly brackets;
the first and the second assembly brackets are mounted to a mounting location on the front of the server rack using a mounting opening of each of the first and the second assembly brackets among a plurality of mounting openings located vertically along a front of each of the first and the second assembly brackets; and
wherein a server is installable in between the first and the second assembly brackets in the server rack while remaining portions of the server rack have power and the cable rail coupled to the first and the second assembly brackets is in the second position.

6. The front cable management assembly of claim 1, wherein:
the cable rail is coupled to a side of each of the first and the second assembly brackets using a plurality of rail fasteners;
the first and the second assembly brackets are coupled to the front of the server rack using a plurality of bracket fasteners, wherein the coupling of the cable rail to the side of each of the first and the second assembly brackets allows power to the server rack to remain on while the cable rail is in the second position and a server installed in the server rack in between the first and the second assembly brackets is accessible; and
wherein the cable rail is to support cables for the server installed in between the first and the second assembly brackets, wherein the cables remain coupled to the cable rail during movement of the cable rail between the first position and the second position.

7. A server rack cable management system, comprising:
a server rack; and
a front cable management assembly including:
a first assembly bracket and a second assembly bracket, wherein the first assembly bracket is mounted to a first side of a front of the server rack and the second assembly bracket is mounted to a second side of the front of the server rack; and
a cable rail movably coupled to a side of each of the first and the second assembly brackets via a plurality of rail fasteners, wherein the cable rail:
is to extend across the front of the server rack and in between the first and the second assembly brackets; and
is to pivot about the plurality of rail fasteners to move positions while coupled to the side of each of the first and the second assembly brackets.

8. The system of claim 7, wherein the front cable management assembly includes:
a plurality of cable rails each coupled to the side of each of the first and the second assembly brackets and in between the first and the second assembly brackets:
wherein each of the plurality of cable rails are to support cables for a server installed in between the first and the second assembly brackets and each of the plurality of cables rails are to move from a respective first position to a respective second position; and
wherein any one of the plurality of servers is serviceable when the cable rail to support cables for the one server is coupled to the first and the second assembly brackets, the cable rail is in the second position, and the remaining plurality of servers have power.

9. The system of claim 7, wherein:
the cable rail is to move from a first position to a second position while movably coupled to the first and the second assembly brackets; and
wherein a server is at least one of installable and uninstallable in between the first and the second assembly brackets when the cable rail is in the second position and coupled to the first and the second assembly brackets.

10. The system of claim 7, wherein the first and the second assembly brackets support a plurality of mounting locations on the front of the server rack, wherein the plurality of mounting locations includes 1 rack unit mounting locations and 0.5 rack unit mounting locations in a vertical direction along the front of the server rack.

11. The system of claim 7, wherein the front cable management assembly supports servers with incremental heights of whole number rack units and incremental heights of half number rack units when the first and the second assembly brackets are mounted to the front of the server rack and the cable rail is horizontally positioned across the front of the server rack and in between the first and the second assembly brackets.

12. A server rack cable management system, comprising:
a server rack; and
a front cable management assembly mounted to front of the server rack including:
a first assembly bracket and a second assembly bracket, wherein the first and the second assembly brackets include:
a plurality of mounting openings located on a front of each of the first and the second assembly brackets to support a plurality of mounting locations on the front of the server rack: and
wherein the first and the second assembly brackets are mounted to the front of the server rack at a mounting location among the plurality of mounting locations using a mounting opening of each of the first and the second assembly brackets among the plurality of mounting openings; and
a cable rail movably coupled to the first and the second assembly brackets, wherein the cable rail:
is to extend across the front of the server rack and in between the first and the second assembly brackets; and
is to move to a first position and a second position while movably coupled to the first and the second assembly brackets.

13. The system of claim 12, wherein the mounting opening supports a first server installable in between the first and the second assembly brackets mounted to the front of the server rack when the cable rail is coupled to the first and the second assembly brackets, with an incremental height that includes a whole number rack unit.

14. The system of claim 13, wherein:
the cable rail is a first cable rail; and
the mounting opening supports a second server installable in between the first and the second assembly brackets mounted to the front of the server rack, when a second cable rail is coupled to the first and the second assembly brackets, with an incremental height that includes a half number rack unit.

15. The system of claim 12, wherein the front cable management assembly is a first front cable management assembly, and the system includes:
a second front cable management assembly mounted to the front of the server rack;
wherein the first and the second assembly brackets of the first front cable management assembly are mounted to the front of the server rack at a first mounting location among the plurality of mounting locations using the mounting opening of each of the first and the second assembly brackets of the first front cable management assembly among the plurality of mounting openings to support a first server installable between the first and the second assembly brackets of the first front cable management assembly with an incremental height that includes a whole number rack unit; and
wherein a first assembly bracket and a second assembly bracket of the second front cable management assembly are mounted to the front of the server rack at a second mounting location among the plurality of mounting locations using a mounting opening of each of the first and the second assembly brackets of the second front cable management assembly among a plurality of mounting openings to support a second server installable between the first and the second assembly brackets of the second front cable management assembly with an incremental height that includes a half number rack unit.
